(19) United States
(12) Patent Application Publication
(10) Pub. No.: US 2025/0118692 A1
(43) Pub. Date: Apr. 10, 2025

(54) Mitigating process problems in hybrid bonding of vertical die stacking

(71) Applicant: Marvell Asia Pte Ltd, Singapore (SG)

(72) Inventor: Runzi Chang, Saratoga, CA (US)

(21) Appl. No.: 18/911,300

(22) Filed: Oct. 10, 2024

Related U.S. Application Data
(60) Provisional application No. 63/543,486, filed on Oct. 10, 2023.

(51) Int. Cl. H01L 23/00; H01L 25/065

(52) U.S. Cl. CPC H01L 24/06; H01L 24/03; H01L 24/05; H01L 24/08; H01L 24/80; H01L 25/0657; H01L 2224/03616; H01L 2224/05546; H01L 2224/05557; H01L 2224/05558; H01L 2224/05559; H01L 2224/0603; H01L 2224/08145; H01L 2224/80895; H01L 2224/80896; H01L 2924/3025

(57) ABSTRACT

An electronic device includes a first integrated circuit (IC) die and a second IC die. The second IC die is mounted on the first IC die. The first IC die includes (i) a first dielectric layer having a first dielectric surface, and (ii) a first pad having a first footprint and a first pad surface, the first pad being electrically conductive and being at least partially embedded in the first dielectric layer. The second IC die includes (i) a second dielectric layer having a second dielectric surface at least partially facing the first dielectric surface, and (ii) a second pad, which is electrically conductive and is at least partially embedded in the second dielectric layer. The second pad has a second footprint, smaller than the first footprint, and a second pad surface electrically coupled to the first pad surface.

### CROSS-REFERENCE TO RELATED APPLICATIONS

This application claims the benefit of U.S. Provisional Patent Application 63/543,486, filed Oct. 10, 2023, whose disclosure is incorporated herein by reference.

### FIELD OF THE DISCLOSURE

The present invention relates generally to packaging of electronic devices, and particularly to methods and systems for improving electrical coupling between integrated circuit (IC) dies stacked in a package.

### BACKGROUND

Hybrid bonding techniques are used for stacking integrated circuit (IC) dies (and for stacking other devices such as chiplets). Each IC die has a dielectric layer with electrically conductive bond pads. The outer surfaces of the bond pads and the dielectric layer are exposed. In a pair of devices stacked using hybrid bonding, both dielectric-to-dielectric and metal-to-metal bonds are formed between the stacked dies. It is noted that compared to other techniques, such as micro-bumps, hybrid bonding enables a substantial increase (e. g., up to 1,000×) of input/output (I/O) connections between the stacked IC dies. The stacking is typically carried out using pick and place (PP) techniques. The increased number of I/O connections dictates smaller pads (e.g., having a pitch smaller than 10 μm) compared to that of the micro-bumps (e.g., larger than 30 μm), and therefore requires improved placement accuracy in the IC die stacking. As such, process problems such as misalignment between the pads of the stacked IC dies may result in electrical shorts and/or cross talks between pads of adjacent pairs, and a convex shape of the outer surface of the pads (also known as dishing) may increase the electrical resistance between the pads of the stacked IC dies.

The description above is presented as a general overview of related art in this field and should not be construed as an admission that any of the information it contains constitutes prior art against the present patent application.

### SUMMARY

An embodiment that is described herein provides an electronic device including a first integrated circuit (IC) die and a second IC die. The second IC die is mounted on the first IC die. The first IC die includes (i) a first dielectric layer having a first dielectric surface, and (ii) a first pad having a first footprint and a first pad surface, the first pad being electrically conductive and being at least partially embedded in the first dielectric layer. The second IC die includes (i) a second dielectric layer having a second dielectric surface at least partially facing the first dielectric surface, and (ii) a second pad, which is electrically conductive and is at least partially embedded in the second dielectric layer. The second pad has a second footprint, smaller than the first footprint, and a second pad surface electrically coupled to the first pad surface.

In some embodiments, the first pad surface is flush with the first dielectric surface, and the second pad surface is flush with the second dielectric surface. In other embodiments, the first pad is recessed with respect to the first dielectric surface, and the second pad surface protrudes out from the second dielectric surface.

There is additionally provided, in accordance with an embodiment that is described herein, a method for fabricating an electronic device. The method includes fabricating a first integrated circuit (IC) die including (i) a first dielectric layer having a first dielectric surface, and (ii) a first pad having a first footprint and a first pad surface, the first pad being electrically conductive and being at least partially embedded in the first dielectric layer. A second IC die is fabricated, the second IC die including (i) a second dielectric layer having a second dielectric surface at least partially facing the first dielectric surface, and (ii) a second pad, which is electrically conductive and is at least partially embedded in the second dielectric layer. The second pad has a second footprint, smaller than the first footprint, and a second pad surface electrically coupled to the first pad surface. The second IC die is mounted on the first IC die.

In some embodiments, mounting the second IC die on the first IC die includes applying a hybrid bonding process. In some embodiments, fabricating the first IC die and the second IC die includes embedding the first pad in the first dielectric layer, and embedding the first pad in the first dielectric layer, by applying a damascene process.

In some embodiments, fabricating the first IC die includes fabricating the first pad surface flush with the first dielectric surface, and fabricating the second IC die includes fabricating the second pad surface flush with the second dielectric surface. In alternative embodiments, fabricating the first IC die includes forming the first pad recessed with respect to the first dielectric surface, and fabricating the second IC die includes forming the second pad surface to protrude out from the second dielectric surface.

In example embodiments, forming the first pad recessed with respect to the first dielectric surface, and forming the second pad surface to protrude out from the second dielectric surface, includes applying a chemical mechanical planarization (CMP) process or a metal etching process.

In a disclosed embodiment, forming the first pad recessed with respect to the first dielectric surface includes recessing a first thickness of the first pad. In an example embodiment, forming the second pad surface to protrude out from the second dielectric surface includes recessing a second thickness of the second dielectric layer. In an embodiment, the first thickness and the second thickness are equal.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device having stacked IC dies, with corresponding pads differing in footprint, in accordance with an embodiment that is described herein;

FIG. 2 is a schematic, sectional view of an electronic device having stacked IC dies, with corresponding pads differing in footprint and protruding/recessed, in accordance with another embodiment that is described herein; and

FIG. 3 is a flow chart that schematically illustrates a method for fabricating the electronic device of FIG. 2, in accordance with an embodiment that is described herein.

### DETAILED DESCRIPTION OF EMBODIMENTS

Embodiments of the present disclosure that are described herein provide techniques for improving electrical performance of electronic devices comprising stacked IC dies, by mitigating process problems in hybrid bonding of vertical stacking of IC dies.

As will be explained in detail below, in some embodiments a pair of IC dies is stacked using hybrid bonding. A pair of corresponding pads (one on each die) face one another. The two pads differ from each other in footprint (e.g., width, length, diameter or any other suitable lateral dimension). Additionally, or alternatively, one of the pads in the pair is recessed relative to the dielectric layer of the die, and the other pad in the pair protrudes from the dielectric layer of the other die. These features reduce sensitivity to placement misalignment between the two dies, and reduce dishing. The disclosed solution may slightly reduce the achievable pad density, but this degradation is typically acceptable in view of the improved process robustness.

In some embodiments, an electronic device comprises a first IC die, and a second IC die mounted on the first IC die. The first IC die comprises (i) a first dielectric layer having a first dielectric surface, and (ii) first electrically conductive pads that are at least partially embedded in the first dielectric layer. Each of the first pads has a first footprint (e.g., width, length or diameter) and a first pad surface. The second IC die comprises (i) a second dielectric layer having a second dielectric surface at least partially facing the first dielectric surface of the first IC die, and (ii) second conductive pads at least partially embedded in the second dielectric layer. At least one of (and typically each) of the second pads has a second footprint, smaller than the first footprint of the respective first pad and a second pad surface electrically coupled to the first pad surface.

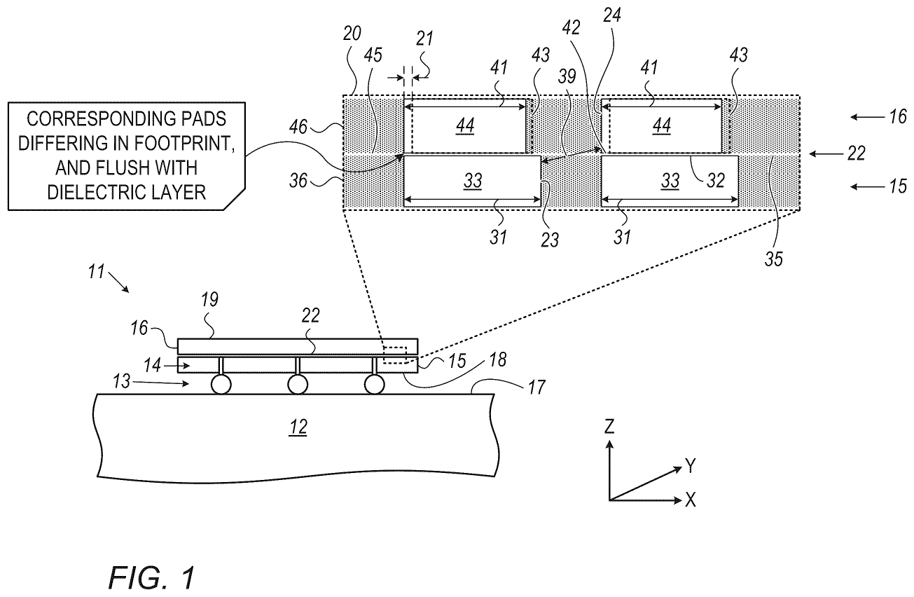

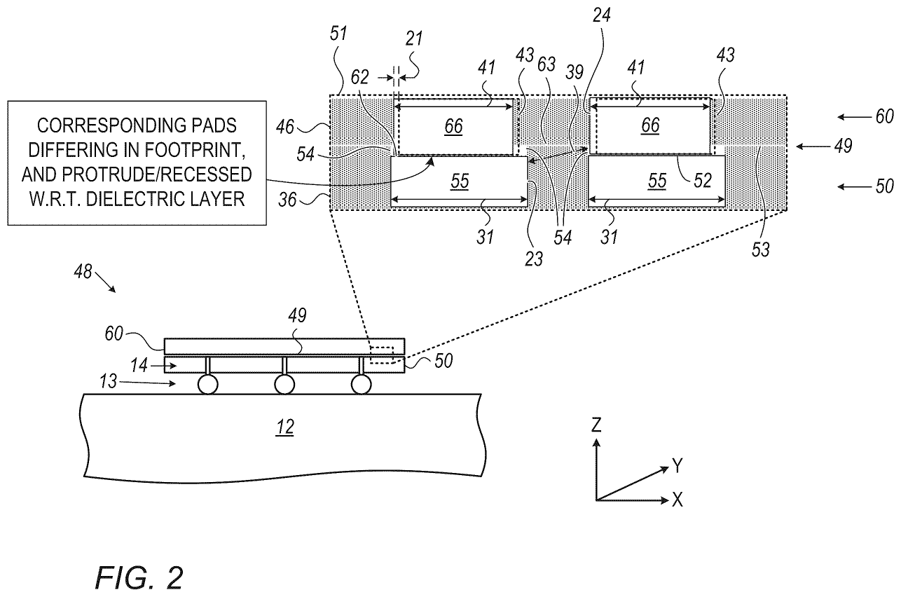

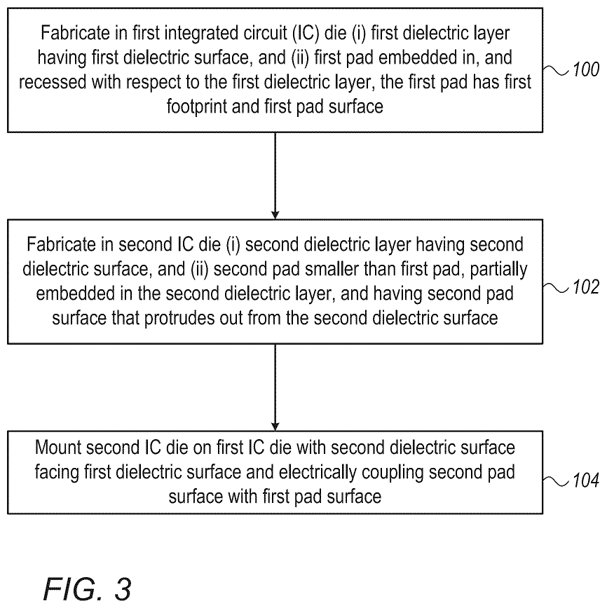

In some embodiments, in the first IC die the first surface of the first pads is recessed with respect to the first dielectric surface, and in the second IC die, the second pad surface of the second pads protrude out from the second dielectric surface. This configuration enables self-alignment between the protruding second pads and the recessed first pads. Moreover, the smaller footprint of the second pads (compared to that of the first pads) compensates for misalignments between pairs of the first and second pads (typically caused by placement error of the second IC die over the first IC die), and thereby, prevents electrical shorts between adjacent pairs of pads. Configurations of electronic devices having stacked IC dies using hybrid bonding are described in FIGS. 1 and 2, and a process for fabricating such electronic devices is described in FIG. 3 below.

The description above is presented as a general overview of embodiments of the present disclosure, which are described in detail herein.

FIG. 1 is a schematic, sectional view of an electronic device 11, in accordance with an embodiment that is described herein.

In some embodiments, electronic device 11 comprises a package substrate 12, typically a laminate substrate, an integrated circuit (IC) die 15, and terminals such as bumps 13 (or micro-bumps) disposed between surfaces 17 and 18 of package substrate 12 and IC die 15, respectively. In alternative embodiments, instead of bumps 13, electronic device 11 comprises micro-bumps or pads, such as pads 33 and 44 described below. The pads may be formed over surfaces 17 and 18, or alternatively, embedded in package substrate 12 and IC die 15. In both configurations the pads are electrically and mechanically coupled to one another using techniques described below. In some embodiments, IC die 15 comprises through-silicon vias 14 configured to conduct electrical signals and/or power and ground between bumps 13 and the ICs of IC die 15.

In some embodiments, electronic device 11 comprises an additional IC die 16 stacked on IC die 15. Each of IC dies 15 and 16 comprises a front side with an active surface having integrated circuits (not shown), and a backside opposite the front side. In the present example, surfaces 18 and 19 are at the backsides of respective IC dies 15 and 16, and the front-sides of IC dies 15 and 16 face one another at an interface 22 and are described in detail herein.

Since the front-sides of IC dies 15 and 16 face each other, the outermost layer of each die is an electrically insulating dielectric layer. Bond pads are disposed in the dielectric layer where interconnections are needed between the IC dies.

Reference is now made to an inset 20 showing interface 22 between a portion of the active sides of IC dies 15 and 16. Most of the area of interface 22 comprises dielectric layers that face one another and electrically insulate dies 15 and 16 from one another. Pairs of bond pads are disposed in the dielectric layers to form electrical interconnections between the circuitries on dies 15 and 16.

In some embodiments, IC die 15 comprises a dielectric layer 36 deposited over the integrated circuits (not shown) of IC die 15, and pads 33 embedded in dielectric layer 36. Dielectric layer 36 is made, for example, from TEOS silicon dioxide, Florine doped silicon dioxide, or from any other suitable dielectric material. Pads 33 are made from copper or from any other suitable electrically conductive material and have a width 31 along the X-axis between about 2 μm and 6 μm.

In the present example, pads 33 may have a square shape in XY plane, so that the width along the Y-axis is similar to that of width 31. Alternatively, pads 33 may have a rectangular shape in XY plane, so that the width is different along the X- and Y-axes. In some embodiments, outer surfaces 32 and 35 of respective pads 33 and dielectric layer 36 are flush with one another.

The description herein refers mainly to square or rectangular pads and to differing widths of the pads. In alternative embodiments, the disclosed technique can be used with pads having any other suitable shapes, e.g., circular, and with any other dimension of the footprints of the pads.

In some embodiments, IC die 16 comprises a dielectric layer 46 deposited over the integrated circuits (not shown) of IC die 16 and pads 44 embedded in dielectric layer 46, which pads typically are made from the same material as pads 33. In the present example, the outer surfaces 42 and 45 of respective pads 44 and dielectric layer 46 are flush with one another. In some embodiments, pads 44 have a width 41 smaller than width 31 of pads 33. Pads 44 may have a square shape or a rectangular shape in XY plane, as described above for pads 33. It is noted that, in an embodiment, pads 44 have smaller footprints than pads 33 in both X- and Y-axes.

Metallic pads (33 or 44) may be embedded in the dielectric layer (36 or 46) using any suitable process. In an example embodiment, the pads are embedded in the dielectric layer using a damascene process that first forms a cavity in the dielectric and then deposits copper in the cavity.

In some embodiments, IC die 16 is placed over IC die 15 using any suitable pick and place (PP) system (not shown), and surfaces 32 and 42 of respective pads 33 and 44 are electrically (and typically physically) coupled to one another to conduct electrical signals (and optionally power and ground) between IC dies 15 and 16. Moreover, surfaces 35 and 45 of respective dielectric layers 36 and 46 are coupled to one another using any suitable technique. In the present example, the PP system has a placement error 21 between the intended position 43 and the actual position of IC die 16 in X- and Y-axis. The placement error is typically less than about 10% of width 41. It is noted that a distance 39 between edges 23 and 24 of respective pads 33 and 44 must exceed a threshold to prevent shorts and/or cross-talks between adjacent pairs of pads 33 and 44. In some embodiments, by reducing width 41 relative to width 31 a distance 39 is increased, which thereby and reduces the aforementioned risk of shorts and/or cross-talk between the adjacent pairs of pads 33 and 44.

In some embodiments, the design of width 41 (of pads 44) is initially similar to width 31 (of pads 33), and following the placing IC die 16 over IC die 15, the placement error of the PP system is measured using an inspection system (not shown) and the placement error in X- and Y-axes is calculated based on the inspection results. Subsequently, a new set of masks is fabricated to adjust width 41 of pads 44 to compensate for the placement error in X- and Y-axes. For example, the new set of masks is designed using a logic operation applied to the mask database of IC die 16, so as to generate the new set of masks with width 41 optimized to reduce the width of pads 44, and thereby, compensate for the placement error and obtain the maximal contact area between surfaces 32 and 42 in XY plane.

In some embodiments, the compensation is calculated based on the mean plus three sigma of the placement error calculated on the measured pairs of pads 33 and 44. In such embodiments, a given number of pairs of pads 33 and 44 are inspected (using the aforementioned inspection system) to measure placement error reading, and all the recorded readings of the placement errors undergo a statistical calculation that refers to data within three standard deviations from a mean value of the placement error. The technique of mean plus three sigma is typically used in statistical process control (SPC) in the fabrication of semiconductor devices. In other embodiments, the SPC may use any suitable number of standard deviations other than 3, for example, mean plus six standard deviations.

FIG. 2 is a schematic, sectional view of an electronic device 48, in accordance with another embodiment that is described herein. In the present embodiment (unlike the embodiment of FIG. 1 in which the pads are flush with the dielectric layer) the pads protrude from, or are recessed in, the dielectric layer.

In some embodiments, electronic device 48 comprises package substrate 12, an IC die 50, bumps 13 (or micro-bumps or pads described in FIG. 1 above) disposed between package substrate 12 and IC die 50, and an IC die 60 stacked on IC die 50. Both IC dies 50 and 60 comprise a front side with an active surface having ICs (not shown), and a backside opposite the front side. In the present example, the front-sides of IC dies 50 and 60 are facing one another at an interface 49 and are described in detail herein. As noted above, most of the area of interface 49 comprises dielectric layers that face one another and electrically insulate dies 50 and 60 from one another. Pairs of bond pads are disposed in the dielectric layers to form electrical interconnections between the circuitries on dies 50 and 60.

Reference is now made to an inset 51 showing interface 49 between a portion of the active sides of IC dies 50 and 60. In some embodiments, IC die 50 comprises dielectric layer 36 deposited over the integrated circuits (not shown) of IC die 50, and pads 55 embedded in dielectric layer 36. Pads 55 are made from copper or from any other suitable electrically conductive material and have width 31 similar to that of pads 33 of electronic device 11. In some embodiments, at least one of (and typically all) pads 55 are recessed with respect to an outer surface 53 of dielectric layer 36, the depth of the recess along the Z-axis is between about 10 nm and 200 nm. As such, an outer surface 52 of pads 55 is recessed along the Z-axis, between about 10 nm and 200 nm, relative to surface 53 of dielectric layer 36.

In some embodiments, IC die 60 comprises dielectric layer 46 deposited over the integrated circuits (not shown) of IC die 60. Dielectric layer 46 has an outer surface 63 facing outer surface 53 of dielectric layer 36 and another surface described below. IC die 60 further comprises pads 66 partially embedded in dielectric layer 46, and typically made from the same material as pads 55. Pads 66 have footprints (in the present example widths) 41 smaller than respective footprints (in the present example widths) 31, and an outer surface 62 facing outer surface 52 of respective pads 55. In the present example, surface 63 of dielectric layer 46 is recessed along the Z-axis between about 10 nm and 200 nm so that the outer surface 62 of pads 66 protrudes in the same range (between about 10 nm and 200 nm) out from surface 63 of dielectric layer 46. Moreover, due to the difference in widths 31 and 41, a section of surface 63 (of dielectric layer 46) is facing surface 52 of pads 55.

In some embodiments, IC die 60 is placed over IC die 50 using the aforementioned PP system, and surfaces 52 and 62 of respective pads 55 and 66 are fused to one another to form a mechanical connection and conduct electrical signals (and optionally power and ground) between IC dies 50 and 60. Moreover, surfaces 53 and 63 of respective dielectric layers 36 and 46 are coupled to one another using any suitable technique.

In some embodiments, the recessed pads 55 expose a portion of walls 54, which are used for self-alignment of pads 66 in XY plane during the Pick and place process (by forming recesses into which the corresponding protruding pads 66 can fit). In such embodiments, the protruding surface 62 of pads 66 is inserted by the PP system between walls 54 so as to mitigate the placement error 21 between the intended position 43 and the actual position of IC die 60 in X- and Y-axis. Thus, distance 39 (between edges 23 and 24 of respective pads 55 and 66) exceeds the threshold described in FIG. 1 above to prevent shorts and/or cross-talks between adjacent pairs of pads 55 and 66. In some embodiments, the combination of (i) the recessed pad 55 and protruding surface 62 of pads 66, and (ii) width 41 smaller than width 31, reduces the risk of shorts and/or cross-talk between the adjacent pairs of pads 55 and 66. In other words, the exposed portion of walls 54 function as stoppers in the XY plane to align pads 66 with pads 55 and couple between surfaces 52 and 62 of respective pads 55 and 66.

FIG. 3 is a flow chart that schematically illustrates a method for fabricating electronic device 48, in accordance with an embodiment that is described herein.

The method begins at a first IC die fabrication operation 100 with fabricating in IC die 50 dielectric layer 36 having surface 53, and pads 55 having width 31, and surface 52. Pads 55 are embedded in dielectric layer 36 and are recessed with respect to surface 53 of dielectric layer 36, as described in detail in FIG. 2 above. In some embodiments, the structure of pads 55 and dielectric layer 36 is fabricated by exposing surface 52 of pads 55 and using a chemical mechanical planarization (CMP) or a metal etching process to recess surface 52 of pads 55 to a depth in Z-axis between about 10 nm and 200 nm relative to surface 53, as described in FIG. 2 above. Parameters of the process, e.g., chemicals, down-force used in CMP, speed, and/or slurries, are typically chosen to achieve the desired shapes of the metal and dielectric structures.

At a second IC die fabrication operation 102, (i) dielectric layer 46 having surface 53, and (ii) pads 66 partially embedded in dielectric layer 46, and having surface 62, are fabricated in IC die 60. In some embodiments, the footprint (e.g., width 41) of pads 66 is smaller than the footprint (e.g., width 31) of pads 55, and surface 62 of pads 66 protrudes out from the second dielectric surface, as described in detail in FIG. 2 above.

In some embodiments, the optimization of the lateral dimensions of the pad footprint (in the present example width 41) is carried out by measuring the placement errors in selected pairs of pads 55 and 66 and calculating the three (or any other suitable number of) standard deviations from the mean value of the placement error using the technique described in detail for pads 33 and 44 in FIG. 1 above. After forming pads 66 in dielectric layer 46 (e.g., using a damascene process as described above), a CMP process is carried out to initially have surface 62 of pads 66 and surface 63 of dielectric layer 46 approximately flush. Subsequently, dielectric layer 46 is recessed using a dielectric etch process, in an embodiment, so that surface 62 of pads 66 protrudes from surface 63 of dielectric layer 46 by the same depth difference (e.g., between about 10 nm and 200 nm) between surfaces 52 and 53 as described in FIG. 2 above.

At an IC die mounting operation 104 that concludes the method, IC die 60 is mounted on IC die 50 with dielectric surfaces 53 and 63 facing one another, and pad surfaces 62 and 52 electrically coupled with one another. It is noted that the depth of the metal recess of pads 55 (carried out in operation 100 above) must be equal to the depth of the dielectric recess of dielectric layer 46 (carried out in operation 102 above) to enable a physical contact between surfaces 53 and 63 of respective dielectric layers 36 and 46 at interface 49, as described in FIG. 2 above.

In some embodiments, before mounting IC die 60 over IC die 50, a surface preparation process may be applied to (i) surfaces 52 and 53 of IC die 50, and (ii) surfaces 62 and 63 of IC die 60. For example, hydrogen plasma may be applied to remove an oxide layer that may have undesirably formed on surfaces 52 and 62 of respective pads 55 and 66. Moreover, after mounting IC die 60 over IC die 50, an annealing process at a temperature between about 150° C. and 350° C. is applied to the stacked IC dies 50 and 60, so as to (i) bond surface 53 with surface 63, and (ii) fuse surface 52 with surface 62. In some embodiments, the combination of (i) the recessed pad 55 and protruding surface 62 of pads 66, and (ii) having width 41 smaller than width 31, mitigates placement errors in XY plane by the PP system, and thereby, reduces the risk of shorts and/or cross-talk between adjacent pairs of pads 55 and 66, as described in detail in FIG. 2 above.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a first integrated circuit (IC) die, comprising:
a first dielectric layer having a first dielectric surface; and
a first pad having a first footprint and a first pad surface, the first pad being electrically conductive and being at least partially embedded in the first dielectric layer; and
a second IC die mounted on the first IC die, the second IC die comprising:
a second dielectric layer having a second dielectric surface at least partially facing the first dielectric surface; and
a second pad, which is electrically conductive and is at least partially embedded in the second dielectric layer, the second pad having a second footprint, smaller than the first footprint, and a second pad surface electrically coupled to the first pad surface.

2. The electronic device according to claim 1, wherein the first pad surface is flush with the first dielectric surface, and the second pad surface is flush with the second dielectric surface.

3. The electronic device according to claim 1, wherein the first pad is recessed with respect to the first dielectric surface, and the second pad surface protrudes out from the second dielectric surface.

4. A method for fabricating an electronic device, the method comprising:
fabricating a first integrated circuit (IC) die comprising:
a first dielectric layer having a first dielectric surface; and
a first pad having a first footprint and a first pad surface, the first pad being electrically conductive and being at least partially embedded in the first dielectric layer; and
fabricating a second IC die comprising:
a second dielectric layer having a second dielectric surface at least partially facing the first dielectric surface; and
a second pad, which is electrically conductive and is at least partially embedded in the second dielectric layer, the second pad having a second footprint, smaller than the first footprint, and a second pad surface electrically coupled to the first pad surface; and
mounting the second IC die on the first IC die.

5. The method according to claim 4, wherein mounting the second IC die on the first IC die comprises applying a hybrid bonding process.

6. The method according to claim 4, wherein fabricating the first IC die and the second IC die comprises embedding the first pad in the first dielectric layer, and embedding the first pad in the first dielectric layer, by applying a damascene process.

7. The method according to claim 4, wherein fabricating the first IC die comprises fabricating the first pad surface flush with the first dielectric surface, and fabricating the second IC die comprises fabricating the second pad surface flush with the second dielectric surface.

8. The method according to claim 4, wherein fabricating the first IC die comprises forming the first pad recessed with respect to the first dielectric surface, and fabricating the second IC die comprises forming the second pad surface to protrude out from the second dielectric surface.

9. The method according to claim 8, wherein forming the first pad recessed with respect to the first dielectric surface, and forming the second pad surface to protrude out from the second dielectric surface, comprises applying a chemical mechanical planarization (CMP) process or a metal etching process.

10. The method according to claim 8, wherein forming the first pad recessed with respect to the first dielectric surface comprises recessing a first thickness of the first pad.

11. The method according to claim 10, wherein forming the second pad surface to protrude out from the second dielectric surface comprises recessing a second thickness of the second dielectric layer.

12. The method according to claim 11, wherein the first thickness and the second thickness are equal.
